(19) United States
(12) Patent Application Publication
(10) Pub. No.: US 2011/0290541 A1
(43) Pub. Date: Dec. 1, 2011

(54) FLEXIBLE FLAT CABLE

(76) Inventor: Shih-Kun YEH, Lu-Chu Hsiang (TW)

(21) Appl. No.: 12/849,290

(22) Filed: Aug. 3, 2010

(30) Foreign Application Priority Data
May 28, 2010 (TW) 099210130

(51) Int. Cl. H05K 1/09; H05K 1/00

(52) U.S. Cl. 174/257; 174/250; 174/258

(57) ABSTRACT

A flexible flat cable includes a first insulating layer, a conductive wire layer, a second insulating layer, a metal layer and at least one grounding element. The conductive wire layer includes a plurality metal wires arranged with interspace and disposed on the first insulating layer, wherein the plurality of metal wires of the conductive wire layer include at least one ground wire. The second insulating layer is disposed on the conductive wire layer and exposes the two ends of the conductive wire layer. The metal layer is disposed on the second insulating layer. The grounding element electrically connects the exposed ground wire and the metal layer.

### BACKGROUND OF THE INVENTION

1. Field of the Invention

The present invention is related to a flexible flat cable, and more particularly to a flexible flat cable with a simple structure and a grounding structure.

2. Description of the Prior Art

With the rapid advancement of electronic technology, various electronic products have been getting more widely applied in our work and life daily. In different kinds of electronic products, flexible flat cables are used frequently as the means for signal transmission.

In practical applications, a flexible flat cable has a plurality of interspaced metal wires, wherein at least one metal wire is a ground wire. The ground wire of the flexible flat cable is then connected to a ground device externally. A prior art technology requires a hole to be disposed on insulating layers wrapping the metal wire to expose the ground wire. Such structure not only increases the complexity of fabrication process, but also raises the manufacturing cost.

### SUMMARY OF THE INVENTION

The present invention is directed to a flexible flat cable which utilizes a grounding element to connect the exposed ground wire with the metal layer disposed on the second insulating layer, whereby a structure with the grounding function is provided for the flexible flat cable.

The flexible flat cable according to an embodiment includes a first insulating layer, a conductive wire layer, a second insulating layer, a metal layer and at least one grounding element. The conductive wire layer includes a plurality of metal wires arranged with interspace, and disposed on the first insulating layer, wherein the plurality of metal wires include at least one ground wire. The second insulating layer is disposed on the conductive wire layer and exposes the two ends of the conductive wire layer. The metal layer is disposed on the second insulating layer. The grounding element is electrically connected to the exposed ground wire and the metal layer.

The objective, technologies, features and advantages of the present invention will become more apparent from the following description in conjunction with the accompanying drawings, wherein certain embodiments of the present invention are set forth by way of illustration and examples.

### BRIEF DESCRIPTION OF THE DRAWINGS

FIG. 1 is a schematic diagram illustrating the structure of the flexible flat cable according to an embodiment of the present invention;

FIG. 2 is a top-view diagram of the flexible flat cable according to an embodiment of the present invention;

FIG. 3 is a schematic diagram illustrating the structure of the flexible flat cable according to another embodiment of the present invention;

FIG. 4 is a schematic diagram illustrating the structure of the flexible flat cable according to another embodiment of the present invention;

FIG. 5 is a schematic diagram illustrating the structure of the flexible flat cable according to another embodiment of the present invention; and

FIG. 6 is a schematic diagram illustrating the structure of the flexible flat cable according to another embodiment of the present invention.

### DESCRIPTION OF THE PREFERRED EMBODIMENT

The detail description of the present invention is provided as follows. The described preferred embodiments are for the purpose of description and illustration, and should not be used to limit the scope of the present invention.

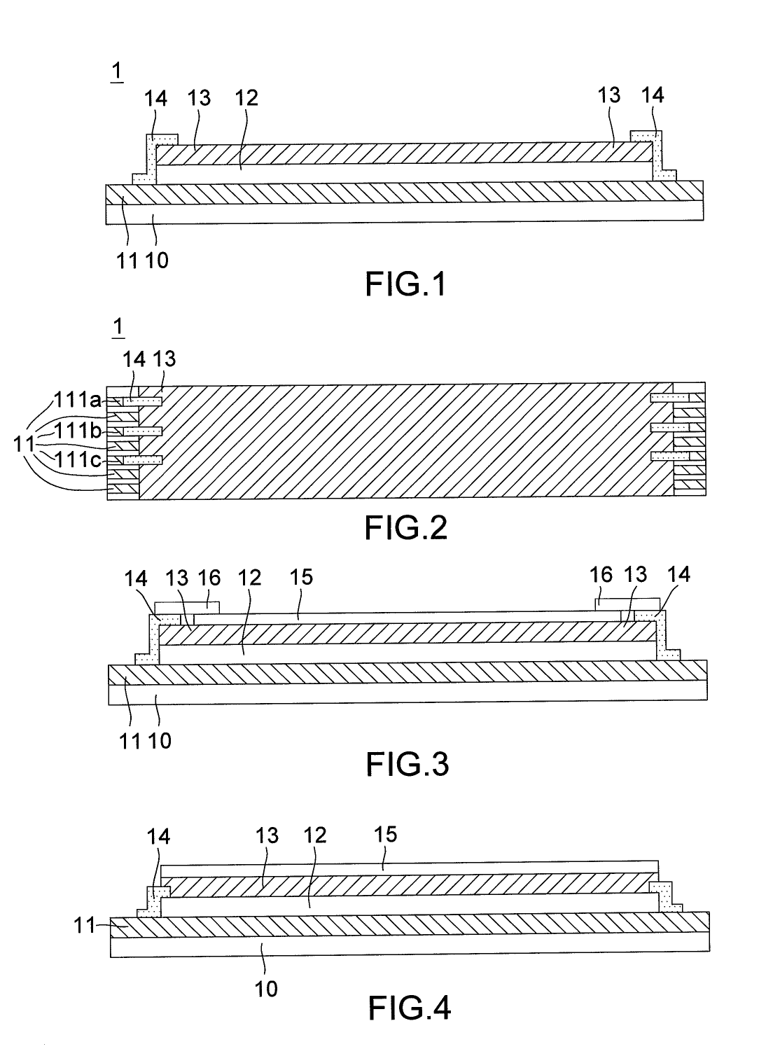

Referring to FIG. 1 and FIG. 2, FIG. 1 is a schematic diagram illustrating the structure of the flexible flat cable 1 according to an embodiment; FIG. 2 is a top-view diagram of the flexible flat cable 1 according to an embodiment. The flexible flat cable 1 includes a first insulating layer 10, a conductive wire layer 11, a second insulating layer 12, a metal layer 13 and at least one grounding element 14. The conductive wire layer 11 includes a plurality of metal wires arranged with interspace and disposed on the first insulating layer 10, wherein the plurality of metal wires include at least one ground wire. For example, the conductive wire layer 11 of the flexible flat cable 1 includes ground wires 111a, 111b, 111c. The second insulating layer 12 is disposed on the conductive wire layer 11 and exposes the two ends of the conductive wire layer 11. The metal layer 13 is disposed on the second insulating layer 12. The grounding element 14 is electrically connected to the exposed ground wires 111a, 111b, 111c and the metal layer 13.

FIG. 3 illustrates the flexible flat cable according to another embodiment. The flexible flat cable further includes a first protecting element 15 and a second protecting element 16, wherein the first protecting element 15 is disposed on the metal layer 13, and the second protecting element 16 covers at least part of the grounding element 14. In the embodiment as shown in FIG. 3, the second protecting element 16 further covers part of the first protecting element 15, but the second protecting element 16 is not limited to be implemented as such. The first protecting element 15 and the second protecting element 16 are for blocking the pollution from such as the external dusts and particles, and also for preventing the grounding element 14 and/or the metal layer 13 from being scratched or worn. The first protecting element 15 and the second protecting element 16 are made of an insulating material, which can include but not limited to polyethylene terephthalate (PET). It is understood that the first protecting element 15 and the second protecting element 16 may also be a constructing element of one piece form. According to another embodiment, the flexible flat cable further includes a reinforcement plate (not shown) disposed on at least one end of the lower surface of the insulating layer 10 to cushion the bumping forces applied on the flexible flat cable, whereby the probability of the occurrence of rupture is decreased. The material of the reinforcement plate can for example include polyester resin.

It has to be explained that for the flexible flat cable 1 according to the present embodiment as shown in FIG. 1 for example, part of the grounding element 14 is disposed on the metal layer 13, and the metal layer 13 covers the second insulating layer 12, but the present invention is not limited to be implemented as such. FIG. 4 is the flexible flat cable according to another embodiment. The metal layer 13 can also partially cover the second insulating layer 12, and part of the grounding element 14 is disposed between the metal layer 13 and the second insulating layer 12. Besides, the grounding element 14 is made of a conductive material which can include but not limited to silver paste or conductive carbon paste, and can be disposed on the conductive wire layer 11 and the second insulating layer 12 through a method such as coating and screen printing. The material of the first insulating layer 10 and the second insulating layer 12 can include but not limited to polyethylene terephthalate (PET), and the metal layer 13 is made of a conductive metal material, which can include but not limited to gold, silver or aluminum.

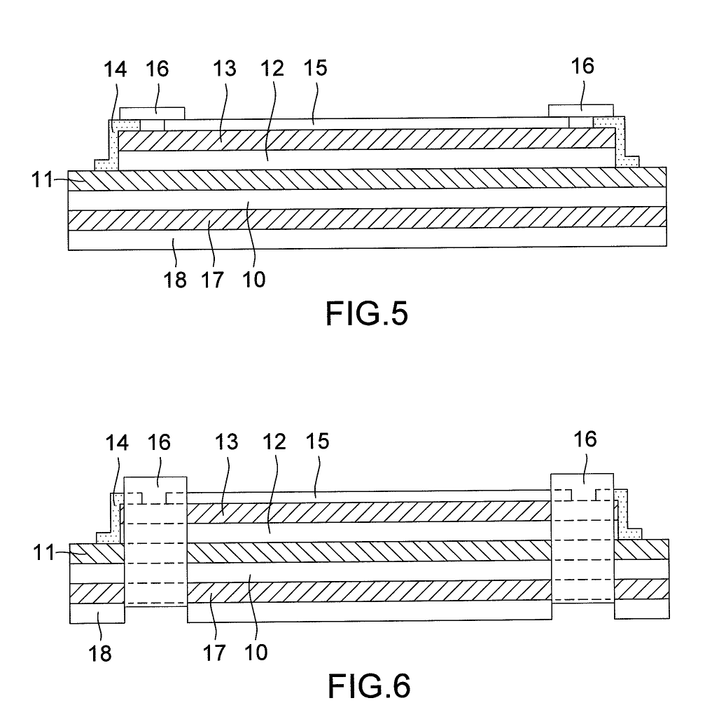

FIG. 5 illustrates the flexible flat cable according to another embodiment. The flexible flat cable further includes a metal shielding layer 17 and a third insulating layer 18, wherein the metal shielding layer 17 is disposed on the lower surface of the first insulating layer 10, and the third insulating layer 18 is disposed on the lower surface of the metal shielding layer 17. The material of the third insulating layer 18 can include but not limited to polyethylene terephthalate (PET). The material of the metal shielding layer 17 includes silver paste or conductive carbon paste. The addition of the metal shielding layer is for lowering the electromagnetic interference and reducing noise interference, and for arranging the characteristic impedance of the flexible flat cable to be in the range of 90Ω to 110Ω, so as to meet the requirement of the usage standard of the Low Voltage Differential Signal (LVDS) transmission line.

FIG. 6 illustrates the flexible flat cable according to another embodiment, wherein the second protecting element 16 covering part of the grounding element 14 can be a jacket disposed on at least one end of the first insulating layer 10, and covering part of the grounding element 14, part of the first protecting element 15, part of the metal shielding layer 17, part of the first insulating layer 10, part of the conductive wire layer 11, part of the second insulating layer 12, and part of the metal layer 13, and exposing the two ends of the conductive wire layer 11. In such way, not only the grounding element 14 may be protected, but the strength of the end arranged with the jacket may also be increased, thereby avoiding rupture. Besides, in the foregoing embodiments, the grounding element is disposed on the two ends of the exposed ground wire of the conductive wire layer. The grounding element may also be disposed on only one end of the ground wire according to the practical need. As we can know from the above embodiments, the spirit of the present invention should encompass all the structures which utilize the grounding element to connect the exposed ground wire of the conductive wire layer with the metal layer disposed on the second insulating layer.

In summary, the flexible flat cable according to the present invention utilizes the grounding element to connect the exposed ground wire of the conductive wire layer and the metal layer disposed on the second insulating layer. The fabrication process of the present invention is simple, fast and the manufacturing cost of the present invention is reduced.

While the invention is susceptible to various modifications and alternative forms, a specific example thereof has been shown in the drawings and is herein described in detail. It should be understood, however, that the invention is not to be limited to the particular form disclosed, but to the contrary, the invention is to cover all modifications, equivalents, and alternatives falling within the spirit and scope of the appended claims.

What is claimed is:

1. A flexible flat cable comprising:
a first insulating layer;
a conductive wire layer comprising a plurality of metal wires arranged with interspace, and disposed on the first insulating layer, wherein the plurality of metal wires comprise at least one ground wire;
a second insulating layer disposed on the conductive wire layer and exposing the two ends of the conductive wire layer;
a metal layer disposed on the second insulating layer; and
at least one grounding element comprising a conductive material, and electrically connected to the exposed ground wire and the metal layer.

2. The flexible flat cable according to claim 1, wherein a portion of the grounding element is disposed between the metal layer and the second insulating layer.

3. The flexible flat cable according to claim 1, wherein a portion of the grounding element is disposed on the metal layer.

4. The flexible flat cable according to claim 1, wherein the metal layer covers the second insulating layer.

5. The flexible flat cable according to claim 1, wherein the metal layer covers a portion of the second insulating layer.

6. The flexible flat cable according to claim 1, wherein the material of the grounding element comprises silver paste or conductive carbon paste.

7. The flexible flat cable according to claim 1, further comprising a reinforcement plate disposed on at least one end of the lower surface of the first insulating layer.

8. The flexible flat cable according to claim 7, wherein the material of the reinforcement plate comprises polyester resin.

9. The flexible flat cable according to claim 1, further comprising a metal shielding layer and a third insulating layer, wherein the metal shielding layer is disposed on the lower surface of the first insulating layer, and the third insulating layer is disposed on the lower surface of the metal shielding layer.

10. The flexible flat cable according to claim 9, wherein the material of the metal shielding layer comprises silver paste or conductive carbon paste.

11. The flexible flat cable according to claim 9, wherein the third insulating layer comprises polyethylene terephthalate (PET).

12. The flexible flat cable according to claim 1, wherein the material of the first and the second insulating layer comprises polyethylene terephthalate (PET).

13. The flexible flat cable according to claim 1, wherein the material of the metal layer is gold, silver or aluminum.

14. The flexible flat cable according to claim 1, further comprising a first protecting element disposed on the metal layer.

15. The flexible flat cable according to claim 14, wherein the material of the first protecting element comprises polyethylene terephthalate (PET).

16. The flexible flat cable according to claim 1, further comprising a second protecting element covering a portion of the grounding element.

17. The flexible flat cable according to claim 16, wherein the second protecting element is a jacket disposed on at least one end of the first insulating layer and exposing two ends of the conductive wire layer.

18. The flexible flat cable according to claim 16, wherein the material of the second protecting element comprises polyethylene terephthalate (PET).
